(19) United States
(12) Patent Application Publication
(10) Pub. No.: US 2025/0254932 A1
(43) Pub. Date: Aug. 7, 2025

(54) SEMICONDUCTOR DEVICE

(71) Applicant: Samsung Electronics Co., Ltd., Suwon-si (KR)

(72) Inventors: Jong Soon PARK, Suwon-si (KR); Tae Hoon LEE, Suwon-si (KR); Back Kyu CHOI, Suwon-si (KR); Seung Ju PARK, Suwon-si (KR); Keun Hee BAI, Suwon-si (KR); Jin Wook LEE, Suwon-si (KR)

(21) Appl. No.: 18/926,563

(22) Filed: Oct. 25, 2024

(30) Foreign Application Priority Data
Feb. 6, 2024 (KR) 10-2024-0018354

(51) Int. Cl. H01L 29/06; H01L 21/768; H01L 29/423; H01L 29/66; H01L 29/775; H01L 29/786

(52) U.S. Cl. CPC H10D 62/10; H01L 21/76829; H10D 30/43; H10D 30/014; H10D 30/6735; H10D 30/6757; H10D 62/121; H10D 62/126

(57) ABSTRACT

A semiconductor device includes a first connection wiring in a first interlayer insulating film, an interlayer etching stop film, a buffer interlayer insulating film, a resistance pattern, a second interlayer insulating film, a wiring via disposed in the second interlayer insulating film and penetrating the buffer interlayer insulating film and the interlayer etching stop film, wherein the wiring via contacts the first connecting wiring, a resistance via disposed in the second interlayer insulating film and contacting the resistance pattern, and a second connection wiring disposed in the second interlayer insulating film and contacting the wiring via and the resistance via. A thickness of the buffer interlayer insulating film between the resistance pattern and the interlayer etching stop film is different from a thickness of the buffer interlayer insulating film through which the wiring via penetrates.

### CROSS-REFERENCE TO RELATED APPLICATION

This application claims priority from Korean Patent Application No. 10-2024-0018354 filed on Feb. 6, 2024 in the Korean Intellectual Property Office and all the benefits accruing therefrom under 35 U.S.C. 119, the contents of which in its entirety are herein incorporated by reference.

### BACKGROUND

### Technical Field

The present disclosure relates to a semiconductor device, and more particularly, to a semiconductor device that includes metallic resistance.

### Description of the Related Art

Recently, as down-scaling of semiconductor elements has been rapidly progressed due to the development of electronic technology, high integration and low power of semiconductor chips have been required. In order to respond to the demand for high integration and low power of semiconductor chips, the feature size of semiconductor devices has continued to be reduced.

As various contact types are used for connection between wirings, a contact length may be increased. For this reason, contact resistance may be increased.

### SUMMARY

An object of the present disclosure is to provide a semiconductor device capable of improving element performance and reliability.

The objects of the present disclosure are not limited to those mentioned above and additional objects of the present disclosure, which are not mentioned herein, will be clearly understood by those skilled in the art from the following description of the present disclosure.

According to an aspect of the present disclosure, a semiconductor device includes a first interlayer insulating film, a first connection wiring disposed in the first interlayer insulating film and extended in a first direction, an interlayer etching stop film on the first interlayer insulating film, a buffer interlayer insulating film on the interlayer etching stop film, a resistance pattern disposed on the buffer interlayer insulating film, a second interlayer insulating film disposed on the buffer interlayer insulating film and the resistance pattern, wherein the second interlayer insulating film includes a low dielectric constant material, a wiring via disposed in the second interlayer insulating film and penetrating the buffer interlayer insulating film and the interlayer etching stop film, wherein the wiring via contacts the first connecting wiring, a resistance via disposed in the second interlayer insulating film and contacting the resistance pattern, and a second connection wiring disposed in the second interlayer insulating film and contacting the wiring via and the resistance via. A thickness of the buffer interlayer insulating film between the resistance pattern and the interlayer etching stop film is different from a thickness of the buffer interlayer insulating film through which the wiring via penetrates.

According to an aspect of the present disclosure, a semiconductor device includes a first interlayer insulating film, a first connection wiring disposed in the first interlayer insulating film and extended in a first direction, an interlayer etching stop film on the first interlayer insulating film, a buffer interlayer insulating film on the interlayer etching stop film, a resistance pattern disposed on the buffer interlayer insulating film, wherein a bottom surface of the resistance pattern contacts the buffer interlayer insulating film, a pattern etching stop film disposed on an upper surface of the resistance pattern, a capping insulating pattern disposed on the pattern etching stop film, a second interlayer insulating film disposed on the buffer interlayer insulating film and the capping insulating pattern, wherein the second interlayer insulating film includes a low dielectric constant material, a wiring via disposed in the second interlayer insulating film, wherein the wiring via penetrates the buffer interlayer insulating film and the interlayer etching stop film and contacts the first connection wiring, a resistance via disposed in the second interlayer insulating film, wherein the resistance via penetrates the capping insulating pattern and the pattern etching stop film and contacts the resistance pattern, and a second connection wiring disposed in the second interlayer insulating film and contacting the wiring via and the resistance via.

According to an aspect of the present disclosure, a semiconductor device includes a first interlayer insulating film, a first connection wiring disposed in the first interlayer insulating film and extended in a first direction, an interlayer etching stop film on the first interlayer insulating film, a buffer interlayer insulating film on the interlayer etching stop film, a resistance pattern disposed on the buffer interlayer insulating film, wherein a bottom surface of the resistance pattern contacts the interlayer etching stop film, a pattern etching stop film disposed on an upper surface of the resistance pattern, wherein the pattern etching stop film and the interlayer etching stop film include a same material, a capping insulating pattern disposed on the pattern etching stop film, a second interlayer insulating film disposed on the buffer interlayer insulating film and the resistance pattern, wherein the second interlayer insulating film includes a low dielectric constant material, a wiring via disposed in the second interlayer insulating film, wherein the wiring via penetrates the buffer interlayer insulating film and the interlayer etching stop film and contacts the first connection wiring, a resistance via disposed in the second interlayer insulating film and contacting the resistance pattern, and a second connection wiring disposed in the second interlayer insulating film and contacting the wiring via and the resistance via. A thickness of the buffer interlayer insulating film between the resistance pattern and the interlayer etching stop film is greater than a thickness of the buffer interlayer insulating film through which the wiring via penetrates.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail illustrative embodiments thereof with reference to the attached drawings, in which:

FIG. 1 is an example layout view illustrating a semiconductor device according to some embodiments.

FIG. 2 is a cross-sectional view taken along line A-A of FIG. 1.

FIG. 3 is a cross-sectional view taken along line B-B of FIG. 1.

FIG. 4 is a view illustrating a semiconductor device according to some embodiments.

FIG. 5 is a view illustrating a semiconductor device according to some embodiments.

FIGS. 6 and 7 are views illustrating a semiconductor device according to some embodiments.

FIG. 8 is a view illustrating a semiconductor device according to some embodiments.

FIG. 9 is a view illustrating a semiconductor device according to some embodiments.

FIGS. 10 to 12 are views illustrating a semiconductor device according to some embodiments.

FIGS. 13 to 18 are views illustrating intermediate steps to describe a method for fabricating a semiconductor device according to some embodiments.

### DETAILED DESCRIPTION OF THE DISCLOSURE

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the drawing related to a semiconductor device according to some embodiments, a fin-type transistor (FinFET) including a channel region of a fin-type pattern shape, a transistor including a nanowire or a nano sheet, a multi-bridge channel field effect transistor (MBCFET™) or a vertical transistor (vertical FET) is shown by way of example, but the present disclosure is not limited thereto. The semiconductor device according to some embodiments may include a tunneling transistor (tunneling FET) or a three-dimensional (3D) transistor. The semiconductor device according to some embodiments may include a planar transistor. In addition, the technical spirits of the present disclosure may be applied to two-dimensional (2D) material-based field effect transistors (2D material based FETs) and a heterogeneous structure thereof.

In addition, the semiconductor device according to some embodiments may include a bipolar junction transistor, a laterally diffused metal oxide semiconductor (LDMOS) transistor and the like.

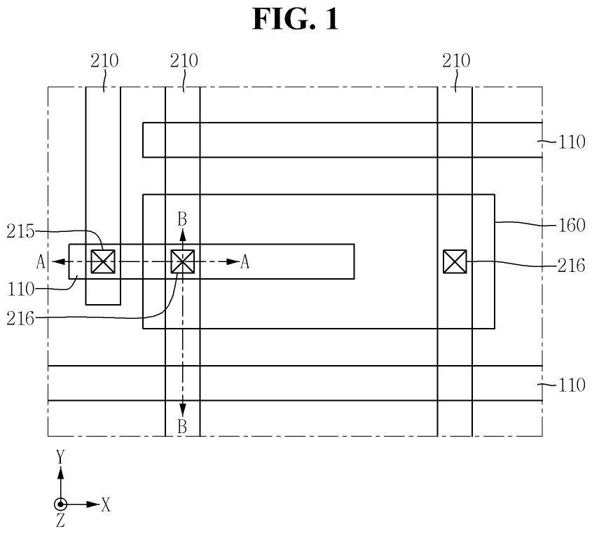

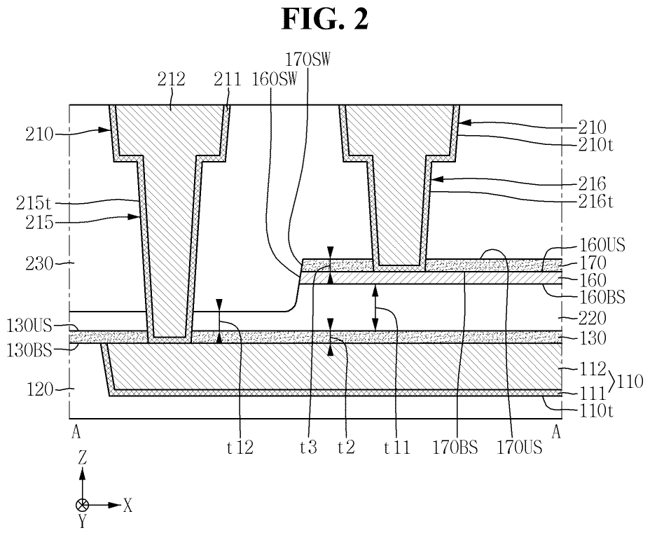

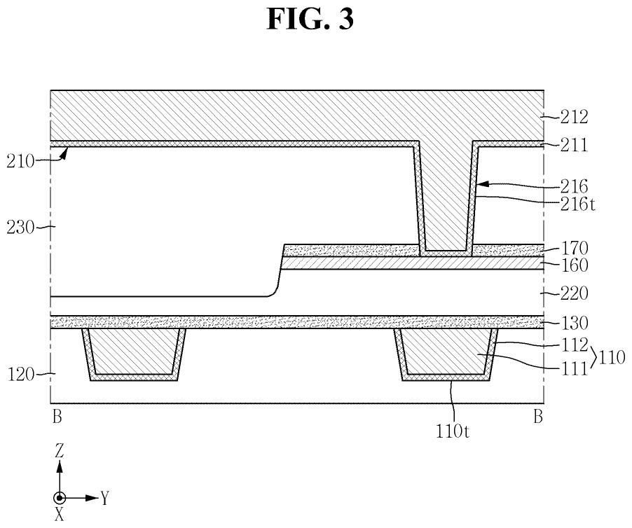

FIG. 1 is an example layout view illustrating a semiconductor device according to some embodiments. FIG. 2 is a cross-sectional view taken along line A-A of FIG. 1. FIG. 3 is a cross-sectional view taken along line B-B of FIG. 1.

Referring to FIGS. 1 to 3, the semiconductor device according to some embodiments may include a first connection wiring 110, a resistance pattern 160, a first interlayer etching stop film 130, a buffer interlayer insulating film 220, a pattern etching stop film 170, a first interlayer insulating film 120, a second interlayer insulating film 230, a second connection wiring 210, a wiring via 215 and a resistance via 216.

The first connection wiring 110 may be disposed in the first interlayer insulating film 120. For example, the first connection wiring 110 may be formed at an upper surface of the first interlayer insulating film 120. An upper surface of the first connection wiring 110 may be coplanar with the upper surface of the first interlayer insulating film 120. The first connection wiring 110 may extend lengthwise in a first direction X.

The first connection wiring 110 may have a line shape extended in the first direction X. For example, the first direction X may be a longitudinal direction of the first connection wiring 110, and a second direction Y may be a width direction of the first connection wiring 110. In this case, the first direction X crosses the second direction Y and a third direction Z. The second direction Y crosses the third direction Z. In an embodiment, the first direction X and the second direction Y may be horizontal directions parallel to the upper surface of the first interlayer insulating film 120, and the third direction Z may be a vertical direction perpendicular to the upper surface of the first interlayer insulating film 120.

The first interlayer insulating film 120 may cover a gate electrode and a source/drain of a transistor formed in a front-end-of-line (FEOL) process. For example, the first interlayer insulating film 120 may be an interlayer insulating film formed in the back-end-of-line (BEOL) process. The first connection wiring 110 may be a connection wiring formed in the back-end-of-line (BEOL) process. In the following description, the first connection wiring 110 is a connection wiring formed in the BEOL process.

The first interlayer insulating film 120 may include or may be formed of at least one of, for example, silicon oxide, silicon nitride, silicon oxynitride and a low dielectric constant material. In the semiconductor device according to some embodiments, the first interlayer insulating film 120 may include a low dielectric constant material to alleviate a coupling phenomenon between wirings. A dielectric constant of the low dielectric constant material has a value less than 3.9, which is a dielectric constant of silicon oxide.

The low dielectric constant material may be, for example, silicon oxide having appropriately high carbon and hydrogen, or may be a material such as SiCOH. In an embodiment, the low dielectric constant material may be, for example, silicon oxide having appropriately high carbon, or may be a material such as SiCO. The low dielectric constant material may include carbon. As carbon is included in the insulating material, a dielectric constant of the insulating material may be lowered. Meanwhile, in order to further reduce a dielectric constant of the insulating material, the insulating material may include a pore, such as a cavity filled with gas or air, in the insulating material.

The low dielectric constant material may include, for example, Fluorinated TetraEthylOrthoSilicate (FTEOS), Hydrogen SilsesQuioxane (HSQ), Bis-benzoCycloButene (BCB), MethylSilsesQuioxane (MQS), TetraMethylOrthoSilicate (TMOS), OctaMethylCycloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), Tonen SilaZen (TOSZ), Carbon Doped silicon Oxide (CDO), Hydrogen Doped silicon oxide, polyimide nanofoams such as polypropylene oxide, Organo Silicate Glass (OSG), Amorphous Fluorinated Carbon, silica aerogels, silica xerogels, mesoporous silica, Aromatic polymer or a combination thereof, but is not limited thereto.

The first connection wiring 110 may be disposed at a first metal level. The first interlayer insulating film 120 may include a first connection wiring trench 110t extended lengthwise in the first direction X.

The first connection wiring 110 may be disposed in the first connection wiring trench 110t. The first connection wiring 110 fills the first connection wiring trench 110t.

The first connection wiring 110 may include a first wiring barrier film 111 and a first wiring filling film 112. The first wiring barrier film 111 may be extended along a sidewall and a bottom surface of the first connection wiring trench 110t.

The first wiring filling film 112 is disposed on the first wiring barrier film 111. The first wiring filling film 112 may fill the remainder of the first connection wiring trench 110t.

The first wiring barrier film 111 may include or may be formed of a conductive material. For example, the first wiring barrier film 111 may include at least one of, for example, tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh) and a two-dimensional (2D) material. The first wiring barrier film 111 is shown as a single film, but is not limited thereto. Unlike the shown example, the first wiring barrier film 111 may include a plurality of conductive films.

In the semiconductor device according to some embodiments, the two-dimensional material may be a metallic material and/or a semiconductor material. The two-dimensional (2D) material may include a two-dimensional allotrope or a two-dimensional compound, and may include at least one of, for example, graphene, boron nitride, molybdenum sulfide, molybdenum selenide, tungsten sulfide, tungsten selenide or tantalum sulfide, but is not limited thereto. That is, since the two-dimensional materials are only listed by way of example, the two-dimensional material that may be included in the semiconductor device of the present disclosure is not limited by the above-described materials.

The first wiring filling film 112 may include or may be formed of at least one of, for example, aluminum (Al), copper (Cu), tungsten (W), cobalt (Co), ruthenium (Ru), silver (Ag), gold (Au), manganese (Mn), molybdenum (Mo), rhodium (Rh), iridium (Ir), RuAl, NiAl, NbB₂, MoB₂, TaB₂, V₂AlC and CrAlC, but is not limited thereto. In the semiconductor device according to some embodiments, the first wiring filling film 112 may include or may be formed of copper (Cu). Copper included in the first wiring filling film 112 may include at least one of, for example, carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), magnesium (Mg), aluminum (Al) or zirconium (Zr).

Unlike the shown example, the first connection wiring 110 may have a single-layered structure. Although not shown, the semiconductor device may further include a via pattern connecting the first connecting wiring 110 to conductive patterns disposed below the first connection wiring 110.

The first connection wiring 110 may be formed using, for example, a damascene process. In FIG. 3, although a width of the first connection wiring 110 in the second direction Y is shown as being reduced as the first connection wiring 110 becomes away from the upper surface of the first interlayer insulating film 120, but is not limited thereto. For example, the first connection wiring 110 may have a decreasing width in a direction away from the upper surface of the first interlayer insulating film 120. The width of the first connection wiring 100 may be measured in the second direction Y. Unlike the shown example, the width of the first connection wiring 110 in the second direction Y may be constant.

In an embodiment, the first connection wiring 110 may be formed using a subtractive etch process. In this case, the width of the first connection wiring 110 in the second direction Y may be increased as the first connection wiring 110 becomes far away from the upper surface of the first interlayer insulating film 120. For example, the first connection wiring 110 may have an increasing width in a direction away from the upper surface of the first interlayer insulating film 120. The width of the first connection wiring 110 may be measured in the second direction Y.

The first interlayer etching stop film 130 may be disposed on the first interlayer insulating film 120. The first interlayer etching stop film 130 may be extended along the upper surface of the first interlayer insulating film 120 and an upper surface of the first connection wiring 110.

The first interlayer etching stop film 130 may include an upper surface 130US and a bottom surface 130BS, which are opposite to each other in the third direction Z. The bottom surface 130BS of the first interlayer etching stop film may face the first connection wiring 110 and the first interlayer insulating film 120.

The first interlayer etching stop film 130 may include a material having etch selectivity with respect to the buffer interlayer insulating film 220. The first interlayer etching stop film 130 may include at least one of, for example, silicon nitride, silicon oxynitride, silicon oxycarbonitride, silicon carbon nitride, silicon boron nitride, silicon oxyboronitride, aluminum oxide, aluminum nitride, aluminum oxycarbide and a combination thereof. Although the first interlayer etching stop film 130 is shown as a single film, it is for convenience of description only, but is not limited thereto. In an embodiment, the first interlayer etching stop film 130 may be a multi-layered film.

In the semiconductor device according to some embodiments, the first interlayer etching stop film 130 may include or may be formed of silicon carbide (SiCN).

The buffer interlayer insulating film 220 may be disposed on the first interlayer etching stop film 130. For example, the buffer interlayer insulating film 220 may be in contact with the upper surface 130US of the first interlayer etching stop film. The term “contact,” or “in contact with” as used herein, refers to a direct connection (i.e., physical touching) unless the context indicates otherwise.

The buffer interlayer insulating film 220 may include or may be formed of at least one of, for example, silicon oxide, silicon nitride and silicon oxynitride. In the semiconductor device according to some embodiments, the buffer interlayer insulating film 220 may include or may be formed of silicon oxide.

The resistance pattern 160 may be disposed on the first connection wiring 110. The resistance pattern 160 may be disposed on the buffer interlayer insulating film 220. When viewed in a plan view, the resistance pattern 160 may have a plate shape.

The resistance pattern 160 may include an upper surface 160US and a bottom surface 160BS, which are opposite to each other in the third direction Z. The bottom surface 160BS of the resistance pattern may face the first interlayer etching stop film 130. The resistance pattern 160 may include a sidewall 160SW connecting the bottom surface 160BS of the resistance pattern to the upper surface 160US of the resistance pattern.

The resistance pattern 160 may be in contact with, for example, the buffer interlayer insulating film 220. The bottom surface 160BS of the resistance pattern may be in contact with the buffer interlayer insulating film 220.

Since the first interlayer etching stop film 130 and the buffer interlayer insulating film 220 are disposed between the resistance pattern 160 and the first connection wiring 110, the resistance pattern 160 may be spaced apart from the first connection wiring 110. Also, the resistance pattern 160 may be spaced apart from the first interlayer etching stop film 130.

The resistance pattern 160 may be disposed on a portion of the buffer interlayer insulating film 220. The buffer interlayer insulating film 220 may include a step difference. In other words, the buffer interlayer insulating film 220 may include a plate region covering the upper surface 130US of the first interlayer etching stop film and a protrusion region protruded from the plate region in the third direction Z. The resistance pattern 160 may be disposed on the protrusion region of the buffer interlayer insulating film 220.

The resistance pattern 160 may include or may be formed of at least one of, for example, metal, conductive metal nitride, conductive metal carbon nitride, conductive metal carbide, metal silicide, a doped semiconductor material, conductive metal oxynitride and conductive metal oxide. Although the resistance pattern 160 is shown as a single film, it is for convenience of description only, but is not limited thereto. In an embodiment, the resistance pattern 160 may be a multi-layered film.

In the semiconductor device according to some embodiments, the resistance pattern 160 may include or may be formed of metal nitride. For example, the resistance pattern 160 may include or may be formed of one of a tantalum nitride (TaN) film, a titanium nitride (TiN) film and a combination thereof. For example, the resistance pattern 160 may include or may be formed of a tantalum nitride (TaN) film. For an example, the resistance pattern 160 may include or may be formed of a titanium nitride (TiN) film. For an example, the resistance pattern 160 may be a multi-layered film that includes a tantalum nitride (TaN) film and a titanium nitride (TiN) film.

The pattern etching stop film 170 may be disposed on the resistance pattern 160. The pattern etching stop film 170 may be disposed between the second interlayer insulating film 230 and the resistance pattern 160.

The pattern etching stop film 170 may include an upper surface 170US and a bottom surface 170BS, which are opposite to each other in the third direction Z. The bottom surface 170BS of the pattern etching stop film may face the resistance pattern 160. The pattern etching stop film 170 may include a sidewall 170SW for connecting the bottom surface 170BS of the pattern etching stop film to the upper surface 170US of the pattern etching stop film.

The pattern etching stop film 170 may be disposed on the upper surface 160US of the resistance pattern. The pattern etching stop film 170 may be extended along the upper surface 160US of the resistance pattern. For example, the pattern etching stop film 170 may be in contact with the upper surface 160US of the resistance pattern.

The pattern etching stop film 170 is not extended along the sidewall 160SW of the resistance pattern. The pattern etching stop film 170 may not cover the sidewall 160SW of the resistance pattern. The pattern etching stop film 170 may not be in contact with the sidewall 160SW of the resistance pattern.

Although the sidewall 160SW of the resistance pattern and the sidewall 170SW of the pattern etching stop film are shown as having an inclination with respect to the third direction Z, the present disclosure is not limited thereto.

The pattern etching stop film 170 may include or may be formed of a material having etch selectivity with respect to the second interlayer insulating film 230. The pattern etching stop film 170 may include or may be formed of at least one of, for example, silicon nitride, silicon oxynitride, silicon oxycarbonitride, silicon carbonitride, silicon boron nitride, silicon oxyboronitride, aluminum oxide, aluminum nitride, aluminum oxycarbide and a combination thereof. Although the pattern etching stop film 170 is shown as a single film, it is for convenience of description only, but is not limited thereto. In an embodiment, the pattern etching stop film 170 may be a multi-layered film.

The pattern etching stop film 170 may include or may be formed of the same material as that of the first interlayer etching stop film 130. For example, the pattern etching stop film 170 may include or may be formed of silicon carbonitride (SiCN).

In the semiconductor device according to some embodiments, a thickness t3 of the pattern etching stop film 170 may be the same as a thickness t2 of the first interlayer etching stop film 130. In this case, the term “same thickness” means that thicknesses of comparison targets are the same, and also means that the thicknesses include a marginal difference which may occur due to a process margin, etc.

The second interlayer insulating film 230 may be disposed on the buffer interlayer insulating film 220 and the resistance pattern 160. The second interlayer insulating film 230 may be disposed on the pattern etching stop film 170. The second interlayer insulating film 230 may be disposed on the upper surface 170US of the pattern etching stop film.

The second interlayer insulating film 230 may include, for example, a low dielectric constant material. The second interlayer insulating film 230 may be in contact with the buffer interlayer insulating film 220.

Since the second interlayer insulating film 230 includes carbon included in an insulating material, a boundary between the buffer interlayer insulating film 220 and the second interlayer insulating film 230 may be distinguished. That is, when the component analysis of the second interlayer insulating film 230 and the buffer interlayer insulating film 220 is performed, the second interlayer insulating film 230 may include carbon, and the buffer interlayer insulating film 220 may not include carbon.

The second interlayer insulating film 230 may include a second connection wiring trench 210t, a wiring via hole 215t and a resistance via hole 216t. The second connection wiring trench 210t may be disposed in the second interlayer insulating film 230.

The second connection wiring trench 210t may be formed at the upper surface of the second interlayer insulating film 230. The wiring via hole 215t may be formed on a bottom surface of the second connection wiring trench 210t. The wiring via hole 215t may be disposed in the second interlayer insulating film 230, the buffer interlayer insulating film 220 and the first interlayer etching stop film 130. The wiring via hole 215t does not pass through the pattern etching stop film 170. The wiring via hole 215t may pass through the buffer interlayer insulating film 220 and the first interlayer etching stop film 130 to expose the first connection wiring 110.

The resistance via hole 216t may be formed on the bottom surface of the second connection wiring trench 210t. The resistance via hole 216t may be disposed in the second interlayer insulating film 230 and the pattern etching stop film 170. The resistance via hole 216t does not pass through the buffer interlayer insulating film 220. The resistance via hole 216t may pass through the second interlayer insulating film 230 and the pattern etching stop film 170 to expose the resistance pattern 160.

The wiring via 215 may be disposed in the second interlayer insulating film 230, the buffer interlayer insulating film 220 and the first interlayer etching stop film 130. The wiring via 215 may be connected to the first connection wiring 110 by passing through the buffer interlayer insulating film 220 and the first interlayer etching stop film 130. The wiring via 215 does not pass through the pattern etching stop film 170. The wiring via 215 may fill the wiring via hole 215t.

The resistance via 216 may be disposed in the second interlayer insulating film 230 and the pattern etching stop film 170. The resistance via 216 may be connected to the resistance pattern 160 by passing through the pattern etching stop film 170. The resistance via 216 does not pass through the buffer interlayer insulating film 220. The resistance via 216 may fill the resistance via hole 216t.

The second connection wiring 210 may be disposed on the first connection wiring 110. The second connection wiring 210 may be disposed on the resistance pattern 160. The resistance pattern 160 may be disposed between the first connection wiring 110 and the second connection wiring 210.

The second connection wiring 210 may be disposed in the second interlayer insulating film 230. The second connection wiring 210 may extend lengthwise in the second direction Y.

The second connection wiring 210 is disposed at a second metal level different from the first metal level. The second connection wiring 210 is disposed at a second metal level higher than the first metal level. Since the resistance pattern 160 is disposed between the first connection wiring 110 and the second connection wiring 210, the resistance pattern 160 may be disposed between the first metal level and the second metal level.

The second connection wiring 210 may be disposed on the wiring via 215 and the resistance via 216. The second connection wiring 210 may be connected to the wiring via 215 and the resistance via 216. The second connection wiring 210 may include a connection wiring connected to the wiring via 215, and a connection wiring connected to the resistance via 216.

A second wiring barrier film 211 may be extended along sidewalls and the bottom surface of the second connection wiring trench 210t, sidewalls and a bottom surface of the wiring via hole 215t and sidewalls and a bottom surface of the resistance via hole 216t. The second wiring filling film 212 may be disposed on the second wiring barrier film 211.

The second connection wiring 210 and the wiring via 215 may include the second wiring barrier film 211 and a second wiring filling film 212. The second connection wiring 210 and the resistance via 216 may include a second wiring barrier film 211 and a second wiring filling film 212.

In other words, each of the second connection wiring 210, the wiring via 215 and the resistance via 216 may include the second wiring barrier film 211 and the second wiring filling film 212. For example, the second connection wiring 210, the wiring via 215 and the resistance via 216 may be formed at the same level. In this case, the term “same level” means that it is formed by the same fabricating process.

Unlike the shown example, the second wiring filling film 212 of the second connection wiring 210 may be separated from the second wiring filling film 212 of the wiring via 215 by the wiring barrier film. Also, the second wiring filling film 212 of the second connection wiring 210 may be separated from the second wiring filling film 212 of the resistance via 216 by the wiring barrier film. In this case, the second connection wiring 210 may be formed in a different fabricating process from the wiring via 215 and the resistance via 216. Even though the second connection wiring 210 is formed in a different fabricating process from the wiring via 215, the wiring via 215 and the resistance via 216 may be formed by the same fabricating process.

The description of the materials included in the second wiring barrier film 211 and the second wiring filling film 212 may be substantially the same as the description of the first wiring barrier film 111 and the first wiring filling film 112. Unlike the shown example, the second connection wiring 210, the wiring via 215 and the resistance via 216 may have a single-layered structure.

Since the buffer interlayer insulating film 220 includes a step difference, a thickness t11 of the buffer interlayer insulating film 220 in a portion where the resistance pattern 160 is disposed may be different from a thickness t12 of the buffer interlayer insulating film 220 in a portion where the resistance pattern 160 is not disposed. In other words, the thickness t11 of the buffer interlayer insulating film 220 between the resistance pattern 160 and the first interlayer etching stop film 130 may be different from the thickness t12 of the buffer interlayer insulating film 220 through which the wiring via 215 penetrates. Since the resistance pattern 160 is disposed on the protrusion region of the buffer interlayer insulating film 220, the thickness t11 of the buffer interlayer insulating film 220 between the resistance pattern 160 and the first interlayer etching stop film 130 may be greater than the thickness t12 of the buffer interlayer insulating film 220 through which the wiring via 215 penetrates.

For example, the thickness t11 of the buffer interlayer insulating film 220 in a portion that is in contact with the bottom surface 160BS of the resistance pattern may be greater than the thickness t12 of the buffer interlayer insulating film 220 in a portion that is not in contact with the bottom surface 160BS of the resistance pattern.

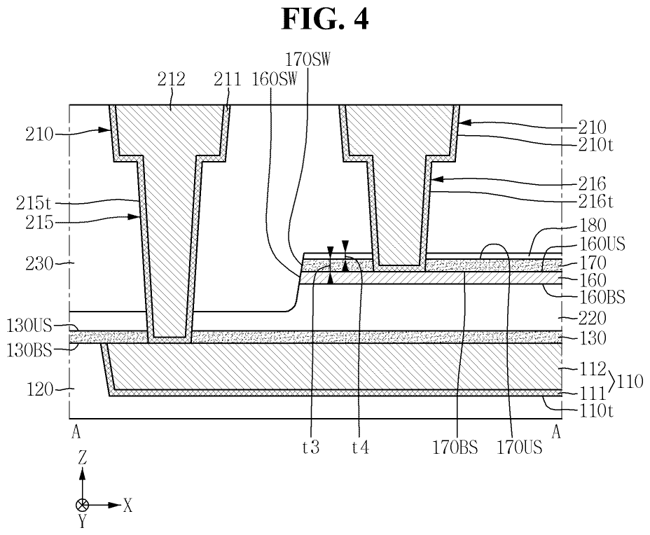

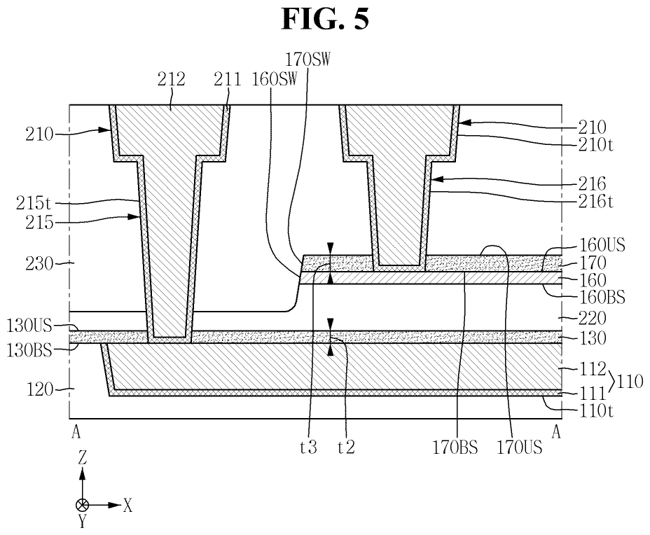

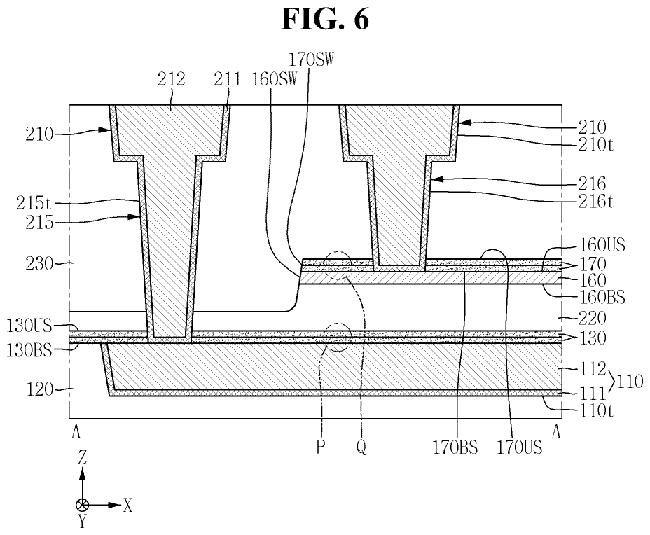

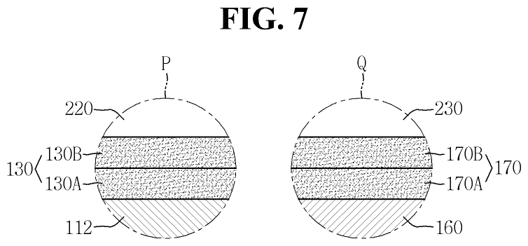

FIG. 4 is a view illustrating a semiconductor device according to some embodiments. FIG. 5 is a view illustrating a semiconductor device according to some embodiments. FIGS. 6 and 7 are views illustrating a semiconductor device according to some embodiments. For convenience of description, the following description will be based on differences from FIGS. 1 to 3.

For reference, FIG. 7 is an enlarged view illustrating portions P and Q of FIG. 6.

Referring to FIG. 4, the semiconductor device according to some embodiments may further include a capping insulating pattern 180.

The capping insulating pattern 180 may be disposed on the pattern etching stop film 170. The capping insulating pattern 180 may be disposed between the second interlayer insulating film 230 and the pattern etching stop film 170.

The second interlayer insulating film 230 may be disposed on the capping insulating pattern 180. For example, the capping insulating pattern 180 may be in contact with the second interlayer insulating film 230 and the pattern etching stop film 170.

The capping insulating pattern 180 may be disposed on the upper surface 170US of the pattern etching stop film. The capping insulating pattern 180 may be in contact with the upper surface 170US of the pattern etching stop film.

The capping insulating pattern 180 is not extended along the sidewall 160SW of the resistance pattern and the sidewall 170SW of the pattern etching stop film. The capping insulating pattern 180 may not cover the sidewall 160SW of the resistance pattern and the sidewall 170SW of the pattern etching stop film. The capping insulating pattern 180 may not be in contact with the sidewall 160SW of the resistance pattern and the sidewall 170SW of the pattern etching stop film.

The resistance via 216 may be connected to the resistance pattern 160 by passing through the capping insulating pattern 180 and the pattern etching stop film 170. While an etching process for forming the resistance pattern 160 is performed, the capping insulating pattern 180 may prevent the pattern etching stop film 170 from being etched.

A thickness t4 of the capping insulating pattern 180 may be smaller than a thickness t3 of the pattern etching stop film 170.

The capping insulating pattern 180 may include or may be formed of a material having etch selectivity with respect to the pattern etching stop film 170. The capping insulating pattern 180 may include or may be formed of at least one of silicon oxide, silicon nitride, silicon oxynitride, silicon boron nitride, silicon oxyboronitride, aluminum oxide, aluminum nitride, aluminum oxycarbide, and a combination thereof. In the semiconductor device according to some embodiments, the capping insulating pattern 180 may include at least one of silicon oxide and silicon nitride.

Referring to FIG. 5, in the semiconductor device according to some embodiments, the thickness t3 of the pattern etching stop film 170 may be different from the thickness t2 of the first interlayer etching stop film 130.

The thickness t3 of the pattern etching stop film 170 may be greater than the thickness t2 of the first interlayer etching stop film 130.

In the fabricating process, the wiring via hole 215t and the resistance via hole 216t may be simultaneously formed. The pattern etching stop film 170 is disposed to be higher than the first interlayer etching stop film 130 relative to the first connection wiring 110. While the wiring via hole 215t and the resistance via hole 216t are formed, the pattern etching stop film 170 may be exposed to be earlier than the first interlayer etching stop film 130.

Until the first interlayer etching stop film 130 is exposed after the formation of the resistance via hole 216t, the pattern etching stop film 170 may be continuously exposed to the etching process, thereby protecting the resistance pattern 160 under the pattern etching stop film 170. As the pattern etching stop film 170 is continuously exposed to the etching process, a portion of the pattern etching stop film 170 may be etched.

Afterwards, while an etching process for removing the pattern etching stop film 170 and the first interlayer etching stop film 130 is performed, the resistance pattern 160 may be exposed to be earlier than the first connection wiring 110. When the resistance pattern 160 is exposed to be earlier than the first connection wiring 110, at least a portion of the resistance pattern 160 may be removed.

When at least a portion of the resistance pattern 160 is removed, a resistance value of the resistance pattern 160 may be different from a resistance value of the resistance pattern 160 intended in the design step of the semiconductor device. Therefore, performance and reliability of the semiconductor device may be deteriorated. To prevent such a problem, the thickness t3 of the pattern etching stop film 170 may be greater than or equal to the thickness t2 of the first interlayer etching stop film 130. In an embodiment, the resistance pattern 160 may serve as a resistor in an electrical circuit, and the pattern etching stop film 170 may serve to protect the resistance pattern 160 during a time when the wiring via hole 215t is formed.

Referring to FIGS. 6 and 7, in the semiconductor device according to some embodiments, each of the first interlayer etching stop film 130 and the pattern etching stop film 170 may include a plurality of silicon carbonitride films.

For example, the first interlayer etching stop film 130 may include a first sub-interlayer etching stop film 130A and a second sub-interlayer etching stop film 130B. The pattern etching stop film 170 may include a first sub-pattern etching stop film 170A and a second sub-pattern etching stop film 170B. Each of the first sub-interlayer etching stop film 130A, the second sub-interlayer etching stop film 130B, the first sub-pattern etching stop film 170A and the second sub-pattern etching stop film 170B may be a silicon carbonitride film.

Although each of the first interlayer etching stop film 130 and the pattern etching stop film 170 is shown as including two silicon carbonitride films, this is for convenience of description only, but is not limited thereto. Unlike the shown example, at least one of the first interlayer etching stop film 130 and the pattern etching stop film 170 may include three or more silicon carbonitride films.

In the semiconductor device according to some embodiments, the number of silicon carbonitride films included in the first interlayer etching stop film 130 may be the same as the number of silicon carbonitride films included in the pattern etching stop film 170.

Unlike the shown example, the number of silicon carbonitride films included in the first interlayer etching stop film 130 may be different from the number of silicon carbonitride films included in the pattern etching stop film 170.

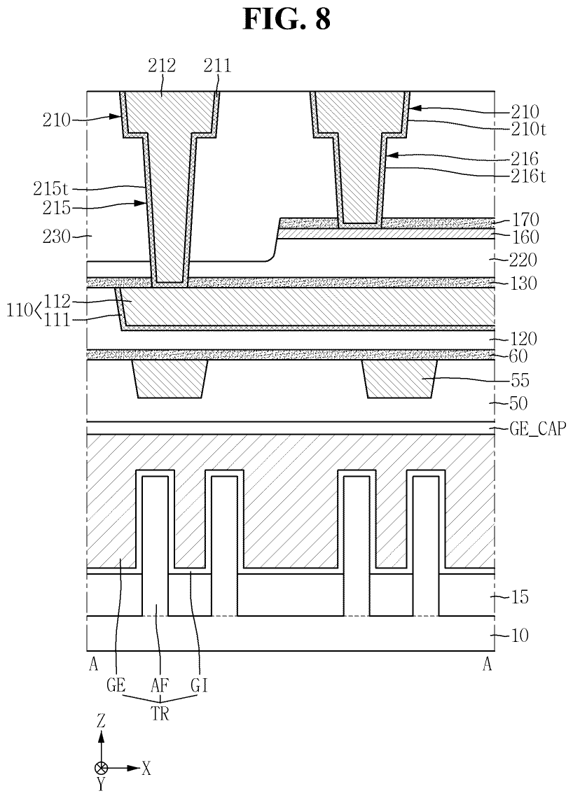

FIG. 8 is a view illustrating a semiconductor device according to some embodiments. For convenience of description, the following description will be based on differences from the description made with reference to FIGS. 1 to 3.

For reference, FIG. 8 is an example view taken along a first gate electrode GE.

In FIG. 8, a fin-type pattern AF is extended lengthwise in the second direction Y, and the first gate electrode GE is extended lengthwise in the first direction X, but the present disclosure is not limited thereto. Unlike the shown example, the fin-type pattern AF may be extended in the first direction X, and the first gate electrode GE may be extended in the second direction Y.

Referring to FIG. 8, the semiconductor device according to some embodiments may include a transistor TR disposed between a substrate 10 and the first connection wiring 110.

The substrate 10 may be a silicon substrate or a silicon-on-insulator (SOI). In an embodiment, the substrate 10 may include silicon germanium, silicon germanium on insulator (SGOI), indium antimonide, lead telluride compound, indium arsenide, indium phosphide, gallium arsenide or gallium antimonide, but is not limited thereto.

The transistor TR may include the fin-type pattern AF, the first gate electrode GE on the fin-type pattern AF, and a first gate insulating film GI between the fin-type pattern AF and the first gate electrode GE.

Although not shown, the transistor TR may include source/drain patterns disposed at opposite sides of the first gate electrode GE.

The fin-type pattern AF may be protruded from the substrate 10. The fin-type pattern AF may extend lengthwise in the second direction Y. The fin-type pattern AF may be a portion of the substrate 10 formed by etching or may include an epitaxial layer grown from the substrate 10. The fin-type pattern AF may include or may be formed of, for example, silicon or germanium, which is an element semiconductor material. Also, the fin-type pattern AF may include or may be formed of a compound semiconductor, and may include or may be formed of, for example, a group IV-IV compound semiconductor or a group III-V compound semiconductor.

The group IV-IV compound semiconductor may be a binary compound or ternary compound, which includes at least two of carbon (C), silicon (Si), germanium (Ge), and tin (Sn), or a compound including at least two of carbon (C), silicon (Si), germanium (Ge), and tin (Sn), which are doped with a group IV element. The group III-V compound semiconductor may be, for example, one of a binary compound, a ternary compound or a quaternary compound, which is formed by combination of at least one of aluminum (Al), gallium (Ga), and indium (In), which is a group III element, and one of phosphorus (P), arsenic (As) and antimony (Sb), which are group V elements.

A field insulating film 15 may be disposed on the substrate 10. The field insulating film 15 may be formed on a portion of a sidewall of the fin-type pattern AF. The fin-type pattern AF may be protruded above an upper surface of the field insulating film 15. The field insulating film 15 may include or may be formed of, for example, an oxide film, a nitride film, an oxynitride film or a combination thereof.

The first gate electrode GE may be disposed on the fin-type pattern AF. The first gate electrode GE may be extended lengthwise in the first direction X. The first gate electrode GE may cross the fin-type pattern AF.

The first gate electrode GE may include or may be formed of at least one of, for example, metal, conductive metal nitride, conductive metal carbonitride, conductive metal carbide, metal silicide, a doped semiconductor material, conductive metal oxynitride, and conductive metal oxide.

The first gate insulating film GI may be disposed between the first gate electrode GE and the fin-type pattern AF and between the first gate electrode GE and the field insulating film 15. The first gate insulating film GI may include or may be formed of, for example, silicon oxide, silicon oxynitride, silicon nitride or a high dielectric constant material having a dielectric constant greater than that of silicon oxide. The high dielectric constant material may include at least one of, for example, boron nitride, metal oxide, and metal silicon oxide.

The semiconductor device according to some embodiments may include a negative capacitance (NC) FET based on a negative capacitor. For example, the first gate insulating film GI may include a ferroelectric material film having ferroelectric characteristics and a paraelectric material film having paraelectric characteristics.

The ferroelectric material film may have a negative capacitance, and the paraelectric material film may have a positive capacitance. For example, when two or more capacitors are connected in series and the capacitance of each capacitor has a positive value, the total capacitance is lower than the capacitance of each individual capacitor. On the other hand, when at least one of capacitances of two or more capacitors connected in series has a negative value, the total capacitance may have a positive value and may be greater than an absolute value of each individual capacitance.

When the ferroelectric material film having a negative capacitance and the paraelectric material film having a positive capacitance are connected in series, the total capacitance value of the ferroelectric material film and the paraelectric material film, which are connected in series, may be increased. Based on the total capacitance value that is increased, a transistor having the ferroelectric material film may have a subthreshold swing (SS) less than 60 mV/decade at a room temperature.

The ferroelectric material film may have ferroelectric characteristics. The ferroelectric material film may include or may be formed of at least one of, for example, hafnium oxide, hafnium zirconium oxide, barium strontium titanium oxide, barium titanium oxide, and lead zirconium titanium oxide. For example, the hafnium zirconium oxide may be a material doped with zirconium (Zr) in hafnium oxide. For example, the hafnium zirconium oxide may be a compound of hafnium (Hf), zirconium (Zr) and oxygen (O).

The ferroelectric material film may further include a dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), or tin (Sn). A type of the dopant included in the ferroelectric material film may be varied depending on the ferroelectric material of the ferroelectric material film.

When the ferroelectric material film includes hafnium oxide, the dopant included in the ferroelectric material film may include at least one of gadolinium (Gd), silicon (Si), zirconium (Zr), aluminum (Al), and yttrium (Y).

When the dopant is aluminum (Al), the ferroelectric material film may include aluminum of 3 atomic % (at %) to 8 at %. In this case, a ratio of the dopant may be a ratio of aluminum to a sum of hafnium and aluminum.

When the dopant is silicon (Si), the ferroelectric material film may include silicon of 2 at % to 10 at %. When the dopant is yttrium (Y), the ferroelectric material film may include yttrium of 2 at % to 10 at %. When the dopant is gadolinium (Gd), the ferroelectric material film may include gadolinium of 1 at % to 7 at %. When the dopant is zirconium (Zr), the ferroelectric material film may include zirconium of 50 at % to 80 at %.

The paraelectric material film may have paraelectric characteristics. The paraelectric material film may include at least one of, for example, silicon oxide, and metal oxide having a high dielectric constant. The metal oxide included in the paraelectric material film may include at least one of, for example, hafnium oxide, zirconium oxide and aluminum oxide, but is not limited thereto.

The ferroelectric material film and the paraelectric material film may include or may be formed of the same material. Although the ferroelectric material film has ferroelectric characteristics, the paraelectric material film may not have ferroelectric characteristics. For example, when the ferroelectric material film and the paraelectric material film include hafnium oxide, a crystal structure of hafnium oxide included in the ferroelectric material film is different from that of hafnium oxide included in the paraelectric material film.

The ferroelectric material film may have a thickness having ferroelectric characteristics. The thickness of the ferroelectric material film may be, for example, 0.5 nm to 10 nm, but is not limited thereto. Since a threshold thickness indicating ferroelectric characteristics may be varied depending on each ferroelectric material, the thickness of the ferroelectric material film may be varied depending on the ferroelectric material.

For example, the first gate insulating film GI may include one ferroelectric material film. The present disclosure is not limited thereto. In an embodiment, the first gate insulating film GI may include a plurality of ferroelectric material films spaced apart from each other. The gate insulating film GI may have a stacked layer structure in which a plurality of ferroelectric material films and a plurality of paraelectric material films are alternately stacked.

A gate capping pattern GE_CAP may be disposed on the first gate electrode GE. The first connection wiring 110 may be disposed on the first gate electrode GE. Although the first connection wiring 110 is shown as being not connected to the first gate electrode GE, the first connection wiring 110 may be connected to the first gate electrode GE.

A lower connection wiring 55 may be disposed between the gate capping pattern GE_CAP and the first connection wiring 110. The lower connection wiring 55 may be disposed in a third interlayer insulating film 50. For example, the lower connection wiring 55 may be formed at an upper surface of the third interlayer insulating film 50. An upper surface of the lower connection wiring 55 may be coplanar with an upper surface of the third interlayer insulating film 50.

The third interlayer insulating film 50 may be disposed between the gate capping pattern GE_CAP and the first interlayer insulating film 120. The third interlayer insulating film 50 may include or may be formed of at least one of, for example, silicon oxide, silicon nitride, silicon oxynitride and a low dielectric constant material.

The lower connection wiring 55 is shown as being extended in the second direction Y, but is not limited thereto. The lower connection wiring 55 may be extended lengthwise in the first direction X.

The lower connection wiring 55 may include or may be formed of at least one of, for example, metal, conductive metal nitride, conductive metal carbonitride, conductive metal carbide, conductive metal oxynitride, conductive metal oxide and a two-dimensional material. Although the lower connection wiring 55 is shown as a single film, it is for convenience of description only, but is not limited thereto. Unlike the shown example, the lower connection wiring 55 may include a wiring barrier film and a wiring filling film like the first connection wiring 110.

A second interlayer etching stop film 60 may be disposed between the third interlayer insulating film 50 and the first interlayer insulating film 120. The second interlayer etching stop film 60 may be extended along an upper surface of the third interlayer insulating film 50 and an upper surface of the lower connection wiring 55. The first interlayer insulating film 120 may be disposed on the second interlayer etching stop film 60.

The second interlayer etching stop film 60 may include or may be formed of at least one of, for example, silicon nitride, silicon oxynitride, silicon oxycarbonitride, silicon carbonitride, silicon boron nitride, silicon oxyboronitride, aluminum oxide, aluminum nitride, aluminum oxycarbide, and a combination thereof. Although the second interlayer etching stop film 60 is shown as a single film, it is for convenience of description only, but is not limited thereto. In an embodiment, the second interlayer etching stop film 60 may be a multi-layered film.

Unlike the shown example, for example, an additional lower connection wiring may be further disposed between the lower connection wiring 55 and the first gate electrode GE. For example, an additional lower connection wiring may be further disposed between the lower connection wiring 55 and the first connection wiring 110.

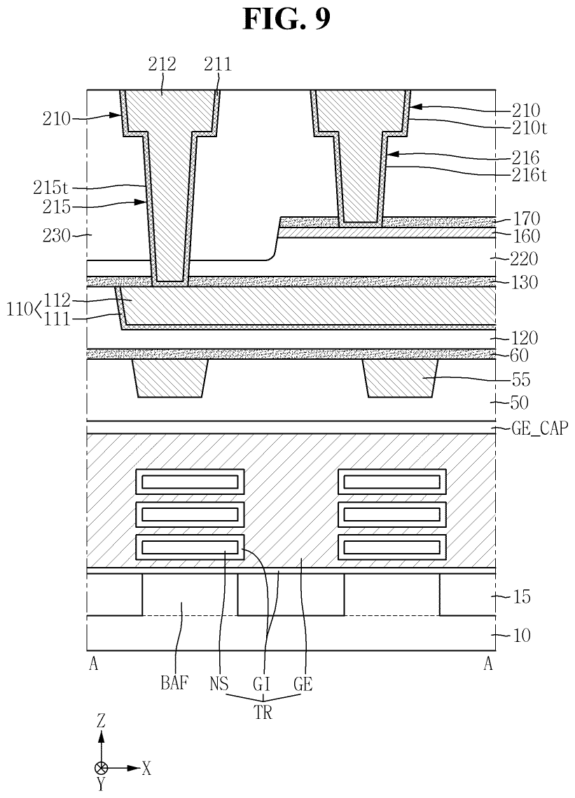

FIG. 9 is a view illustrating a semiconductor device according to some embodiments. For convenience of description, the following description will be based on differences from the description made with reference to FIG. 8.

Referring to FIG. 9, in the semiconductor device according to some embodiments, a transistor TR may include a nanosheet NS, a first gate electrode GE surrounding the nanosheet NS, and a first gate insulating film GI between the nanosheet NS and the first gate electrode GE.

The nanosheet NS may be disposed on a lower fin-type pattern BAF. The nanosheet NS may be spaced apart from the lower fin-type pattern BAF in the third direction Z. Although the transistor TR is shown as including three nanosheets NS spaced apart from one another in the third direction Z, the present disclosure is not limited thereto. The number of nanosheets NS disposed on the lower fin-type pattern BAF in the third direction Z may be greater than or smaller than three.

Each of the lower fin-type pattern BAF and the nanosheet NS may include or may be formed of, for example, silicon or germanium, which is an element semiconductor material. Each of the lower fin-type pattern BAF and the nanosheet NS may include or may be formed of a compound semiconductor, for example, a group IV-IV compound semiconductor or a group III-V compound semiconductor. The lower fin-type pattern BAF and the nanosheet NS may include or may be formed of the same material or different materials.

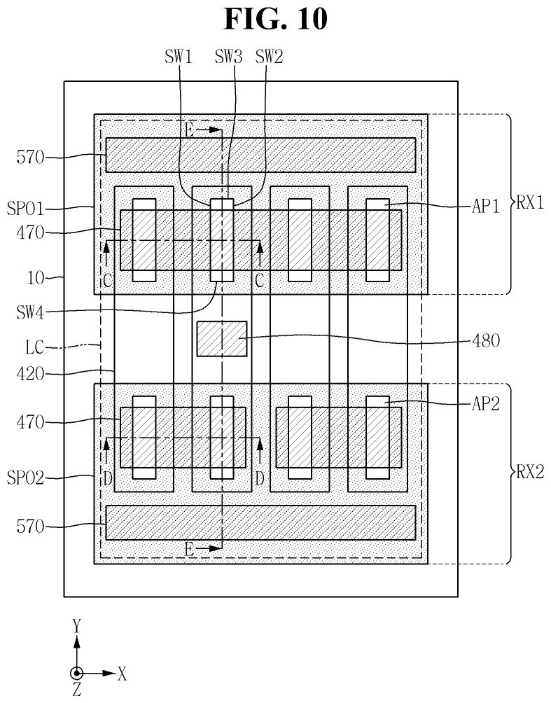

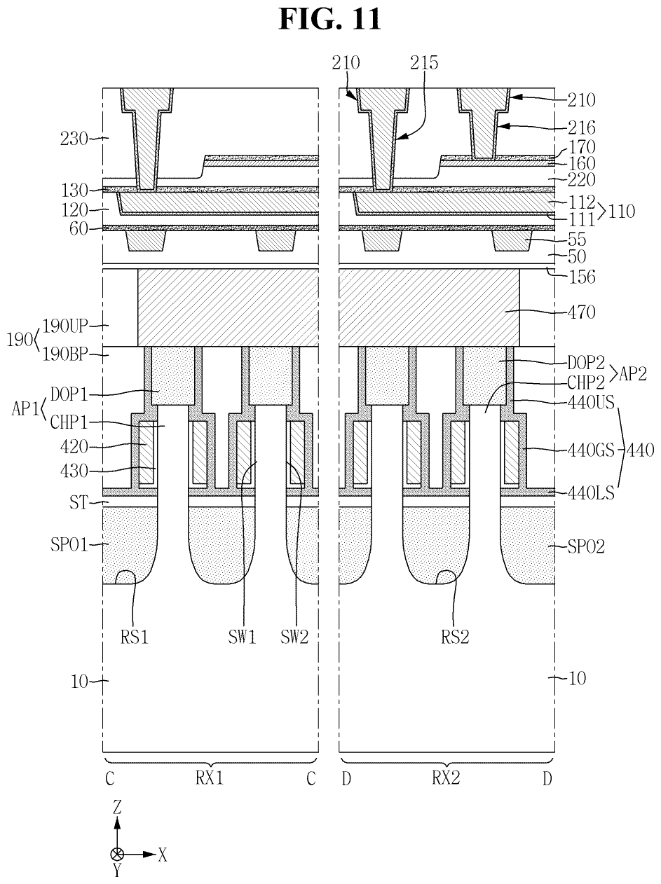

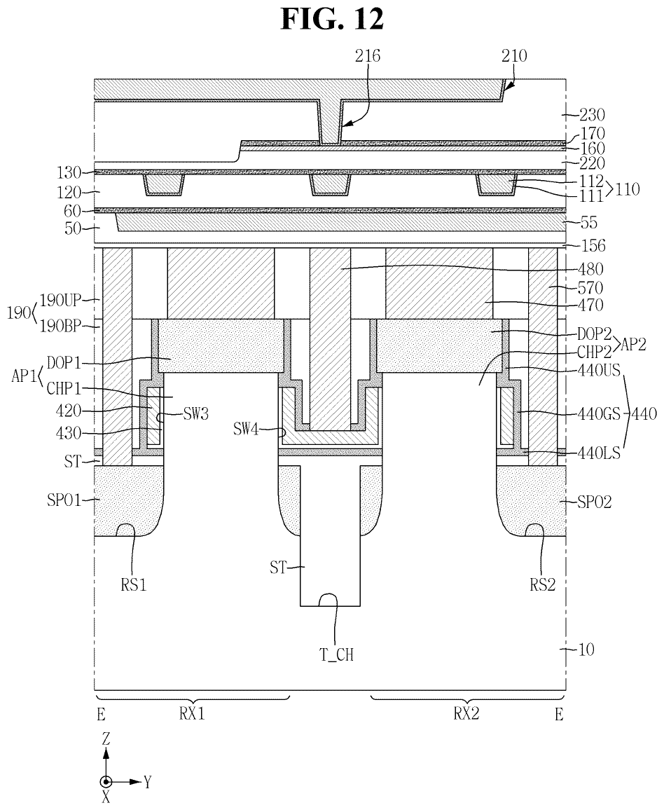

FIGS. 10 to 12 are views illustrating a semiconductor device according to some embodiments. For reference, FIG. 10 is a plan view illustrating a semiconductor device according to some embodiments. FIG. 11 is a cross-sectional view taken along lines C-C and D-D of FIG. 10. FIG. 12 is a cross-sectional view taken along line E-E of FIG. 10.

Referring to FIGS. 10 to 12, a logic cell LC may be provided on the substrate 10. The logic cell LC may refer to a logic element (e.g., an inverter, a flip-flop, etc.) that performs a specific function. The logic cell LC may include vertical transistors (Vertical FETs) constituting a logic element and wirings connecting the vertical transistors with each other.

The logic cell LC on the substrate 10 may include a first active region RX1 and a second active region RX2. For example, the first active region RX1 may be a P-type Metal Oxide Field Effect Transistor (PMOSFET) region, and the second active region RX2 may be an N-type Metal Oxide Field Effect Transistor (NMOSFET) region. The first and second active regions RX1 and RX2 may be defined by a trench T_CH formed in an upper portion of the substrate 10. The first and second active regions RX1 and RX2 may be spaced apart from each other in the second direction Y.

A first lower epitaxial pattern SPO1 may be provided in the first active region RX1, and a second lower epitaxial pattern SPO2 may be provided in the second active region RX2. When viewed in a plan view, the first lower epitaxial pattern SPO1 may overlap the first active region RX1, and the second lower epitaxial pattern SPO2 may overlap the second active region RX2. The first and second lower epitaxial patterns SPO1 and SPO2 may be epitaxial patterns formed by a selective epitaxial growth process. The first lower epitaxial pattern SPO1 may be provided in a first recess region RS1 of the substrate 10, and the second lower epitaxial pattern SPO2 may be provided in a second recess region RS2 of the substrate 10.

The first active patterns AP1 may be provided in the first active region RX1, and the second active patterns AP2 may be provided in the second active region RX2. Each of the first and second active patterns AP1 and AP2 may have a vertically protruded fin shape. When viewed in a plan view, each of the first and second active patterns AP1 and AP2 may have a bar shape extended lengthwise in the second direction Y. The first active patterns AP1 may be arranged along the first direction X, and the second active patterns AP2 may be arranged along the first direction X.

Each of the first active patterns AP1 may include a first channel pattern CHP1 vertically protruded from the first lower epitaxial pattern SPO1 and a first upper epitaxial pattern DOP1 on the first channel pattern CHP1. For example, the first channel pattern CHP1 may extend from a region of the substrate 10 between two adjacent first lower epitaxial patterns SPO1 in the third direction Z direction. The first channel pattern CHP may extend in a direction away from the substrate 10 toward the first connection wiring 110. The two adjacent first lower epitaxial patterns SPO1 may be spaced apart from each other in the first direction X (see FIG. 11). Each of the second active patterns AP2 may include a second channel pattern CHP2 vertically protruded from the second lower epitaxial pattern SPO2 and a second upper epitaxial pattern DOP2 on the second channel pattern CHP2. For example, the second channel pattern CHP2 may extend from a region of the substrate 10 between two adjacent second lower epitaxial patterns SPO2 in the third direction X. The second channel pattern CHP2 may extend in a direction away from the substrate 10 toward the first connection wiring 110. The two adjacent second lower epitaxial patterns SPO2 may be spaced apart from each other in the first direction X (see FIG. 11).

An element isolation film ST may be provided on the substrate 10 to fill the trench T_CH. The element isolation film ST may cover upper surfaces of the first and second lower epitaxial patterns SPO1 and SPO2. The first and second active patterns AP1 and AP2 may be vertically protruded above an upper surface of the element isolation film ST.

A plurality of second gate electrodes 420 extended lengthwise in parallel with each other in the second direction Y may be provided on the element isolation film ST. The second gate electrodes 420 may be arranged along the first direction X. The second gate electrode 420 may surround the first channel pattern CHP1 of the first active pattern AP1, and may surround the second channel pattern CHP2 of the second active pattern AP2. For example, the first channel pattern CHP1 of the first active pattern AP1 may have first to fourth sidewalls SW1 to SW4. The first and second sidewalls SW1 and SW2 may be opposite to each other in the first direction X, and the third and fourth sidewalls SW3 and SW4 may be opposite to each other in the second direction Y. The second gate electrode 420 may be provided on the first to fourth sidewalls SW1 to SW4. In other words, the second gate electrode 420 may surround the first to fourth sidewalls SW1 to SW4.

A second gate insulating film 430 may be interposed between the second gate electrode 420 and each of the first and second channel patterns CHP1 and CHP2. The second gate insulating film 430 may cover a bottom surface of the second gate electrode 420 and an inner sidewall of the second gate electrode 420. For example, the second gate insulating film 430 may directly cover the first to fourth sidewalls SW1 to SW4 of the first active pattern AP1.

The first and second upper epitaxial patterns DOP1 and DOP2 may be vertically disposed above the second gate electrode 420. An upper surface of the second gate electrode 420 may be lower than a bottom surface of each of the first and second upper epitaxial patterns DOP1 and DOP2. In other words, each of the first and second active patterns AP1 and AP2 may have a structure vertically protruded from the substrate 10 to pass through the second gate electrode 420.

The semiconductor device according to some embodiments may include vertical-type transistors in which carriers move in the third direction Z. For example, when a voltage is applied to the second gate electrode 420 and thus the transistor is turned “on”, carriers may move from the lower epitaxial patterns SOP1 and SOP2 to the upper epitaxial patterns DOP1 and DOP2 through the channel patterns CHP1 and CHP2. In the semiconductor device according to some embodiments, the second gate electrode 420 may completely surround the sidewalls SW1 to SW4 of the channel patterns CHP1 and CHP2. The transistor according to the present disclosure may be a three-dimensional field effect transistor (e.g., VFET) having a gate-all-around structure. Since the gate surrounds the channel, the semiconductor device according to some embodiments may have excellent electrical characteristics.

A spacer 440 covering the second gate electrodes 420 and the first and second active patterns AP1 and AP2 may be provided on the element isolation film ST. The spacer 440 may include or may be formed of a silicon nitride film or a silicon oxynitride film. The spacer 440 may include a lower spacer 440LS, an upper spacer 440US and a gate spacer 440GS between the lower and upper spacers 440LS and 440US.

The lower spacer 440LS may directly cover an upper surface of the element isolation film ST. The second gate electrodes 420 may be spaced apart from the element isolation film ST in the third direction Z by the lower spacer 440LS. The gate spacer 440GS may cover an upper surface and an outer sidewall of each of the second gate electrodes 420. The upper spacer 440 may cover the first and second upper epitaxial patterns DOP1 and DOP2. However, the upper spacer 440US may expose upper surfaces of the first and second upper epitaxial patterns DOP1 and DOP2 without covering the upper surfaces of the first and second upper epitaxial patterns DOP1 and DOP2.

A lower interlayer insulating film 190 may include a first portion 190BP and a second portion 190UP. The first portion 190BP of the lower interlayer insulating film may be provided on the spacer 440. An upper surface of the first portion 190BP of the lower interlayer insulating film may be substantially coplanar with the upper surfaces of the first and second upper epitaxial patterns DOP1 and DOP2. The second portion 190UP of the lower interlayer insulating film, the third interlayer insulating film 50, the first interlayer insulating film 120 and the second interlayer insulating film 230 may be sequentially stacked on the first portion 190BP of the lower interlayer insulating film. The second portion 190UP of the lower interlayer insulating film may cover the upper surfaces of the first and second upper epitaxial patterns DOP1 and DOP2. For example, the second portion 190UP may cover a portion of the upper surface of each of the first and second epitaxial patterns DOP1 and DOP2.

At least one first source/drain contact 470 connected to the first and second upper epitaxial patterns DOP1 and DOP2 by passing through the second portion 190UP of the lower interlayer insulating film may be provided. At least one second source/drain contact 570 connected to the first and second lower epitaxial patterns SPO1 and SPO2 by sequentially passing through the lower interlayer insulating film 190, the lower spacer 440LS and the element isolation film ST may be provided. A gate contact 480 connected to the second gate electrode 420 by sequentially passing through the second portion 190UP of the lower interlayer insulating film, the first portion 190BP of the lower interlayer insulating film and the gate spacer 440GS may be provided.

A lower etching stop film 156 may be additionally disposed between the second portion 190UP of the lower interlayer insulating film and the third interlayer insulating film 50. The second interlayer etching stop film 60 may be disposed between the third interlayer insulating film 50 and the first interlayer insulating film 120.

The lower connection wiring 55 may be provided in the third interlayer insulating film 50. The first connection wiring 110 may be provided in the first interlayer insulating film 120. The resistance pattern 160, the first interlayer etching stop film 130, the buffer interlayer insulating film 220, the pattern etching stop film 170, the second interlayer insulating film 230, the second connection wiring 210, the wiring via 215 and the resistance via 216 may be disposed on the first connection wiring 110.

The resistance pattern 160, the first interlayer etching stop film 130, the buffer interlayer insulating film 220, the pattern etching stop film 170, the second interlayer insulating film 230, the second connection wiring 210, the wiring via 215 and the resistance via 216 may be substantially the same as those described with reference to FIGS. 1 to 7.

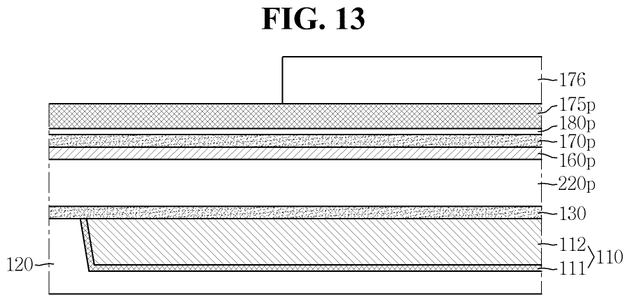

FIGS. 13 to 18 are views illustrating intermediate steps to describe a method of fabricating a semiconductor device according to some embodiments.

For reference, FIGS. 13 to 18 may be drawings taken along line A-A of FIG. 1.

Referring to FIG. 13, a first interlayer etching stop film 130, a pre-buffer interlayer insulating film 220p, a resistance film 160p, a pre-pattern etching stop film 170p and a pre-capping insulating film 180p may be sequentially formed on the first interlayer insulating film 120 on which the first connection wiring 110 is formed.

Unlike the shown example, the pre-capping insulating film 180p may be omitted.

Subsequently, a hard mask film 175p may be formed on the pre-capping insulating film 180p. The hard mask film 175p may include or may be formed of a conductive material. For example, the hard mask film 175p may include or may be formed of titanium nitride, but is not limited thereto.

A mask pattern 176 may be formed on the hard mask film 175p. The mask pattern 176 may include or may be formed of at least one of silicon oxide, silicon nitride, silicon oxynitride, and an organic material.

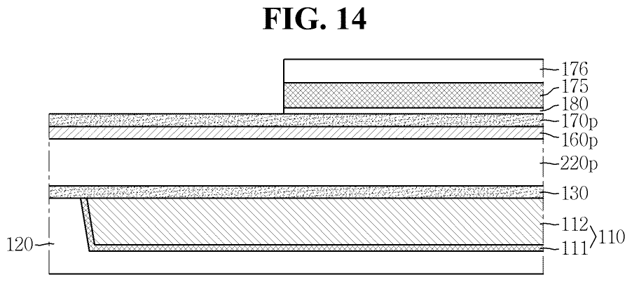

Referring to FIGS. 13 and 14, the hard mask film 175p and the pre-capping insulating film 180p may be patterned to form a hard mask pattern 175 and a capping insulating pattern 180.

The hard mask film 175p and the pre-capping insulating film 180p may be patterned using the mask pattern 176 as an etch mask. As a result, the hard mask pattern 175 and the capping insulating pattern 180 may be formed.

The hard mask pattern 175 and the capping insulating pattern 180 may be formed using, for example, a dry etching process, but is not limited thereto. While the hard mask pattern 175 and the capping insulating pattern 180 are formed, a portion of the mask pattern 176 may be removed. That is, while the hard mask pattern 175 and the capping insulating pattern 180 are formed, the mask pattern 176 may become thin.

Unlike the shown example, the mask pattern 176 may be removed while the hard mask pattern 175 and the capping insulating pattern 180 are formed.

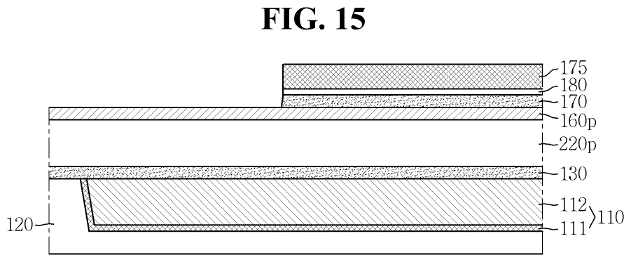

Referring to FIGS. 14 and 15, the pre-pattern etching stop film 170p may be patterned to form the pattern etching stop film 170.

The pre-pattern etching stop film 170p may be patterned using the mask pattern 176 and the hard mask pattern 175 as etch masks. Therefore, the pattern etching stop film 170 may be formed.

The pattern etching stop film 170 may be formed using, for example, a dry etching process, but is not limited thereto. While the pattern etching stop film 170 is formed, the mask pattern 176 may be removed.

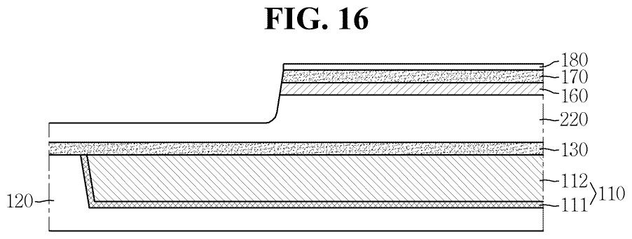

Referring to FIGS. 15 and 16, the resistance film 160p may be patterned to form the resistance pattern 160.

The resistance film 160p may be patterned using the pattern etching stop film 170 as an etch mask. Thus, the resistance pattern 160 may be formed. The resistance pattern 160 may be formed using, for example, a dry etching process.

While the resistance pattern 160 is formed, the hard mask pattern 175 may be removed. Also, while the resistance pattern 160 is formed, a portion of the pre-buffer interlayer insulating film 220p may be etched to form the buffer interlayer insulating film 220. A portion of the pre-buffer interlayer insulating film 220p, which is not covered by the hard mask pattern 175 and the resistance pattern 160, may be removed. A portion of the pre-buffer interlayer insulating film 220p is removed, but the first interlayer etching stop film 130 is not exposed.

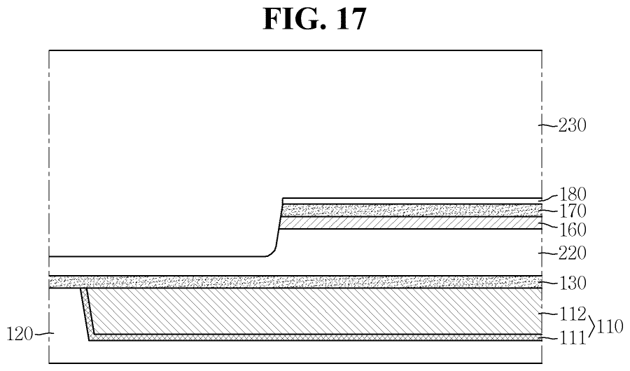

Referring to FIG. 17, the second interlayer insulating film 230 may be formed on the buffer interlayer insulating film 220 and the resistance pattern 160.

The second interlayer insulating film 230 may be formed on the capping insulating pattern 180. The second interlayer insulating film 230 may cover the sidewall of the resistance pattern 160 and the sidewall of the pattern etching stop film 170.

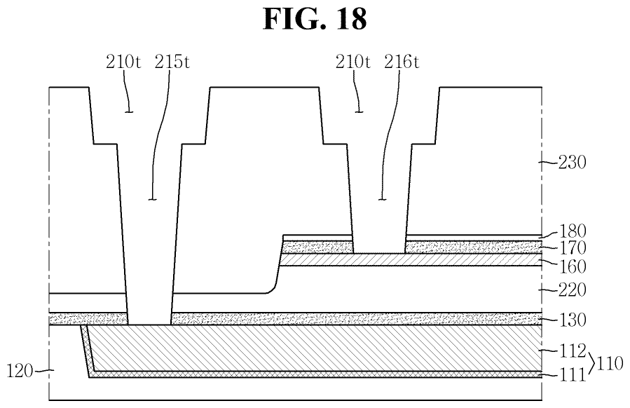

Referring to FIG. 18, the wiring via hole 215t and the resistance via hole 216t may be formed in the second interlayer insulating film 230.

The wiring via hole 215t and the resistance via hole 216t may be simultaneously formed. The wiring via hole 215t may expose the first connection wiring 110 by passing through the buffer interlayer insulating film 220 and the first interlayer etching stop film 130. The resistance via hole 216t may expose the resistance pattern 160 by passing through the capping insulating pattern 180 and the pattern etching stop film 170.

In the process of forming the wiring via hole 215t and the resistance via hole 216t, the second connection wiring trench 210t may be formed.

Subsequently, referring to FIG. 2, the second connection wiring 210, the wiring via 215 and the resistance via 216 may be formed.

The second connection wiring 210 may be formed in the second connection wiring trench 210t. The wiring via 215 may be formed in the wiring via hole 215t. The resistance via 216 may be formed in the resistance via hole 216t.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A semiconductor device comprising:
a first interlayer insulating film;
a first connection wiring disposed in the first interlayer insulating film and extended in a first direction;
an interlayer etching stop film on the first interlayer insulating film;
a buffer interlayer insulating film on the interlayer etching stop film;
a resistance pattern disposed on the buffer interlayer insulating film;
a second interlayer insulating film disposed on the buffer interlayer insulating film and the resistance pattern, wherein the second interlayer insulating film includes a low dielectric constant material;
a wiring via disposed in the second interlayer insulating film and penetrating the buffer interlayer insulating film and the interlayer etching stop film, wherein the wiring via contacts the first connecting wiring;
a resistance via disposed in the second interlayer insulating film and contacting the resistance pattern; and
a second connection wiring disposed in the second interlayer insulating film and contacting the wiring via and the resistance via,
wherein a thickness of the buffer interlayer insulating film between the resistance pattern and the interlayer etching stop film is different from a thickness of the buffer interlayer insulating film through which the wiring via penetrates.

2. The semiconductor device of claim 1,
wherein the thickness of the buffer interlayer insulating film between the resistance pattern and the interlayer etching stop film is greater than the thickness of the buffer interlayer insulating film through which the wiring via passes.

3. The semiconductor device of claim 1, further comprising:
a pattern etching stop film disposed between the resistance pattern and the second interlayer insulating film, wherein the pattern etching stop film contact an upper surface of the resistance pattern,
wherein the resistance via penetrates the pattern etching stop film and contacts the resistance pattern.

4. The semiconductor device of claim 3,
wherein the pattern etching stop film and the interlayer etching stop film includes a same material.

5. The semiconductor device of claim 3,
wherein a thickness of the pattern etching stop film is greater than or equal to a thickness of the interlayer etching stop film.

6. The semiconductor device of claim 3, further comprising:
a capping insulating pattern disposed between the pattern etching stop film and the second interlayer insulating film,
wherein the capping insulating pattern contacts the pattern etching stop film and the second interlayer insulating film, and
wherein the resistance via penetrates the capping insulating pattern and contacts the resistance pattern.

7. The semiconductor device of claim 6,
wherein a thickness of the capping insulating pattern is smaller than a thickness of the pattern etching stop film.

8. The semiconductor device of claim 1,
wherein the buffer interlayer insulating film is in contact with the resistance pattern and the interlayer etching stop film.

9. The semiconductor device of claim 1,
wherein the resistance pattern includes one of a tantalum nitride film, a titanium nitride film, and a combination thereof.

10. The semiconductor device of claim 1,
wherein the interlayer etching stop film includes silicon carbonitride (SiCN).

11. A semiconductor device comprising:
a first interlayer insulating film;
a first connection wiring disposed in the first interlayer insulating film and extended in a first direction;
an interlayer etching stop film on the first interlayer insulating film;
a buffer interlayer insulating film on the interlayer etching stop film;
a resistance pattern disposed on the buffer interlayer insulating film, wherein a bottom surface of the resistance pattern contacts the buffer interlayer insulating film;
a pattern etching stop film disposed on an upper surface of the resistance pattern;
a capping insulating pattern disposed on the pattern etching stop film;
a second interlayer insulating film disposed on the buffer interlayer insulating film and the capping insulating pattern, wherein the second interlayer insulating film includes a low dielectric constant material;
a wiring via disposed in the second interlayer insulating film, wherein the wiring via penetrates the buffer interlayer insulating film and the interlayer etching stop film and contacts the first connection wiring;
a resistance via disposed in the second interlayer insulating film, wherein the resistance via penetrates the capping insulating pattern and the pattern etching stop film and contacts the resistance pattern; and
a second connection wiring disposed in the second interlayer insulating film and contacting the wiring via and the resistance via.

12. The semiconductor device of claim 11,
wherein a thickness of the buffer interlayer insulating film between the resistance pattern and the interlayer etching stop film is greater than a thickness of the buffer interlayer insulating film through which the wiring via penetrates.

13. The semiconductor device of claim 11,
wherein a thickness of the capping insulating pattern is smaller than a thickness of the pattern etching stop film.

14. The semiconductor device of claim 11,
wherein each of the interlayer etching stop film and the pattern etching stop film includes silicon carbonitride (SiCN).

15. The semiconductor device of claim 14,
wherein each of the interlayer etching stop film and the pattern etching stop film includes a plurality of silicon carbonitride films, and
wherein a number of the plurality of silicon carbonitride films included in the interlayer etching stop film is the same as a number of the plurality of silicon carbonitride films included in the pattern etching stop film.

16. The semiconductor device of claim 11,
wherein a thickness of the pattern etching stop film is greater than a thickness of the interlayer etching stop film.

17. The semiconductor device of claim 11,
wherein the resistance pattern includes one of a tantalum nitride film, a titanium nitride film, and a combination thereof.

18. A semiconductor device comprising:
a first interlayer insulating film;
a first connection wiring disposed in the first interlayer insulating film and extended in a first direction;
an interlayer etching stop film on the first interlayer insulating film;
a buffer interlayer insulating film on the interlayer etching stop film;
a resistance pattern disposed on the buffer interlayer insulating film, wherein a bottom surface of the resistance pattern contacts the interlayer etching stop film;
a pattern etching stop film disposed on an upper surface of the resistance pattern, wherein the pattern etching stop film and the interlayer etching stop film include a same material;
a capping insulating pattern disposed on the pattern etching stop film;
a second interlayer insulating film disposed on the buffer interlayer insulating film and the resistance pattern, wherein the second interlayer insulating film includes a low dielectric constant material;
a wiring via disposed in the second interlayer insulating film, wherein the wiring via penetrates the buffer interlayer insulating film and the interlayer etching stop film and contacts the first connection wiring;
a resistance via disposed in the second interlayer insulating film and contacting the resistance pattern; and
a second connection wiring disposed in the second interlayer insulating film and contacting the wiring via and the resistance via,
wherein a thickness of the buffer interlayer insulating film between the resistance pattern and the interlayer etching stop film is greater than a thickness of the buffer interlayer insulating film through which the wiring via penetrates.

19. The semiconductor device of claim 18,
wherein the interlayer etching stop film includes silicon carbonitride (SiCN), and
wherein a thickness of the pattern etching stop film is greater than or equal to a thickness of the interlayer etching stop film.

20. The semiconductor device of claim 18,
wherein the resistance pattern includes a tantalum nitride film.
